(19) United States
(12) Patent Application Publication
(10) Pub. No.: US 2020/0335640 A1
(43) Pub. Date: Oct. 22, 2020

(54) METHODS AND SYSTEMS FOR INSULATED GLASS UNITS WITH ELECTRICAL CONNECTION TO INTERNAL SOLAR PANELS

(71) Applicant: Ubiquitous Energy, Inc., Redwood City, CA (US)

(72) Inventor: Ian Millard, Palo Alto, CA (US)

(73) Assignee: Ubiquitous Energy, Inc., Redwood City, CA (US)

(21) Appl. No.: 16/852,175

(22) Filed: Apr. 17, 2020

Related U.S. Application Data
(60) Provisional application No. 62/836,161, filed on Apr. 19, 2019.

(51) Int. Cl. H01L 31/02; H01L 31/048

(52) U.S. Cl. CPC H01L 31/02013; H01L 31/0488

(57) ABSTRACT

An insulated glass unit (IGU) includes a first glass lite and a solar cell adjacent the first glass lite. The solar cell includes one or more busbars. The IGU also includes a spacer frame joined to the solar cell or the first glass lite and including a plurality of electrical conductors passing through the spacer frame. Each of the plurality of electrical conductors is electrically connected to one of the one or more busbars. The IGU further includes a second glass lite joined to the spacer frame.

### CROSS-REFERENCES TO RELATED APPLICATIONS

This application claims priority to U.S. Provisional Patent Application No. 62/836,161, filed on Apr. 19, 2019, entitled “Methods and Systems for Insulated Glass Units with Electrical Connection to Internal Solar Panels,” the disclosure of which is hereby incorporated by reference in its entirety for all purposes.

### BACKGROUND OF THE INVENTION

Solar cells have been developed that selectively transmit light visible to the human eye while absorbing only the ultraviolet and infrared light and converting it into electricity. Integration of this transparent solar technology with glass lites enables windows (i.e., insulated glass units) to be manufactured that provide natural lighting and a source of onboard power.

Despite the progress made in the field of transparent solar technology, there is a need in the art for improved methods and systems for providing electrical connections to solar panels disposed in insulated glass units.

### SUMMARY OF THE INVENTION

According to embodiments of the present invention, electrical connections that pass through a spacer frame of an insulated glass unit (IGU) are utilized to provide for electrical connectivity between one or more solar panels disposed in the IGU and external electrical systems. Utilizing embodiments of the present invention, a hermetic seal can be formed, preventing gas in the IGU from escaping as well as preventing introduction of gases into the interior of the IGU. Moreover, embodiments of the present invention increase the manufacturability of IGUs by improving the process by which electrical bonding to the electrical busbar of the solar panel is performed.

According to an embodiment of the present invention, an external molded cable, which can be a braided cable, is mechanically separated (from a gas permeation perspective) from internal electrical connectors that are electrically bonded to the busbars of a solar panel. As a result, the internal electrical connectors can be readily bonded to the busbars using, for example, techniques that are suitable for manufacturing. In some embodiments, either corner key integrated electrical connection unit or side-mounted integrated electrical connection units are utilized to enable the mechanical separation, as described more fully herein.

### BRIEF DESCRIPTION OF THE DRAWINGS

FIG. 1A is a simplified schematic diagram illustrating a corner key integrated electrical connection unit according to an embodiment of the present invention.

FIG. 1B is a simplified schematic diagram illustrating a corner key integrated electrical connection unit having a single electrical connector according to an embodiment of the present invention.

FIG. 2A is a simplified schematic diagram illustrating a side-mounted integrated electrical connection unit according to an embodiment of the present invention.

FIG. 2B is a simplified schematic diagram illustrating a side-mounted integrated electrical connection unit having a single electrical connector according to an embodiment of the present invention.

FIG. 3A is simplified plan view schematic diagram illustrating a side-mounted integrated electrical connection unit with two electrical connectors electrically connected to a busbar of a solar panel according to an embodiment of the present invention.

FIG. 3B is a simplified cross sectional view schematic diagram illustrating a side-mounted integrated electrical connection unit with an electrical connector electrically connected to a busbar of a solar panel according to an embodiment of the present invention.

FIG. 4A is a simplified plan view schematic diagram illustrating an IGU including a set of corner key integrated electrical connection units according to an embodiment of the present invention.

FIG. 4B is a simplified cross sectional view schematic diagram illustrating the IGU including a set of corner key integrated electrical connection units shown in FIG. 4A.

FIG. 5 is an exploded perspective view schematic diagram illustrating an IGU including a set of corner key integrated electrical connection units according to an embodiment of the present invention.

FIG. 6 is a simplified flowchart illustrating a method of assembling an insulated glass unit (IGU) with integrated electrical connection units according to an embodiment of the present invention.

### DETAILED DESCRIPTION OF SPECIFIC EMBODIMENTS

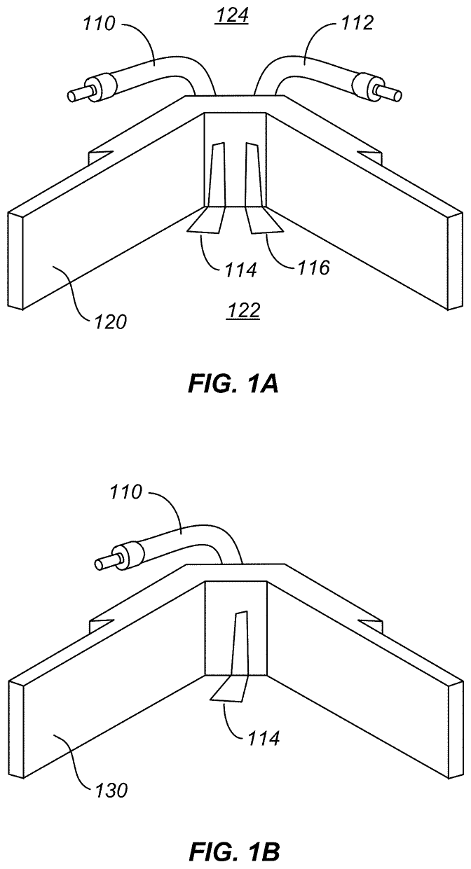

FIG. 1A is a simplified schematic diagram illustrating a corner key integrated electrical connection unit according to an embodiment of the present invention. As illustrated in FIG. 1A, a corner key integrated electrical connection unit having a corner key geometry can be utilized in a corner of a spacer frame to provide mechanical support for the integrated electrical connection unit, which can include one or more electrical conductors and electronics. Referring to FIG. 1A, molded cables 110 and 112 are utilized to provide external electrical connection. The molded cables 110 and 112 can be MC4 style connects or other suitable solar connectors. The molded cables 110 and 112 typically include braided cables. As a result, if the braided cable is exposed to the interior of the IGU, spaces between the braids will enable gas to pass into and out of the IGU, preventing a gas tight seal. Accordingly, embodiments of the present invention provide an electrical connection between molded cables 110 and 112 and electrical connectors 114 and 116 that is discontinuous to the flow of gases. Embodiments of the present invention can utilize molded cables that are water permeable since the braided cables do not pass into the interior of the IGU.

The molded cables 110 and 112 terminate at, or inside, corner key integrated electrical connection unit 120 and are electrically connected to electrical connectors 114 and 116, respectively. In some embodiments, the electrical connection between molded cables 110 and 112 and electrical connectors 114 and 116, respectively, is made at or beyond the external surface of corner key integrated electrical connection unit 120, inside the body of corner key integrated electrical connection unit 120, or at the internal surface of corner key integrated electrical connection unit 120. The corner key integrated electrical connection unit can be fabricated from a variety of materials that are characterized by impermeability to liquids and gases, including plastic, metal, combinations thereof, and the like.

Electrical connectors 114 and 116 can be implemented as flat metal connectors that are bent towards the glass surface, i.e., the solar panel (not shown, but would be present below corner key integrated electrical connection unit 120) with a flat connection area that facilitates bonding, soldering, ultrasonic soldering, epoxy bonding, conductive adhesives, pressure curing, ultraviolet curing, or other suitable electrical connection to one or more busbars present on the solar panel. One of several techniques to provide electrically conductive adhesion can be utilized to mechanically and electrically connect electrical connectors 114 and 116 to the solar panel, including an ultrasonic solder if bonding to glass/oxide surface, standard solder if bonding to a suitable busbar surface, a conductive epoxy, which can be solvent free and can be cured using either thermal or an ultraviolet cure process, a conductive pressure sensitive adhesive, or the like.

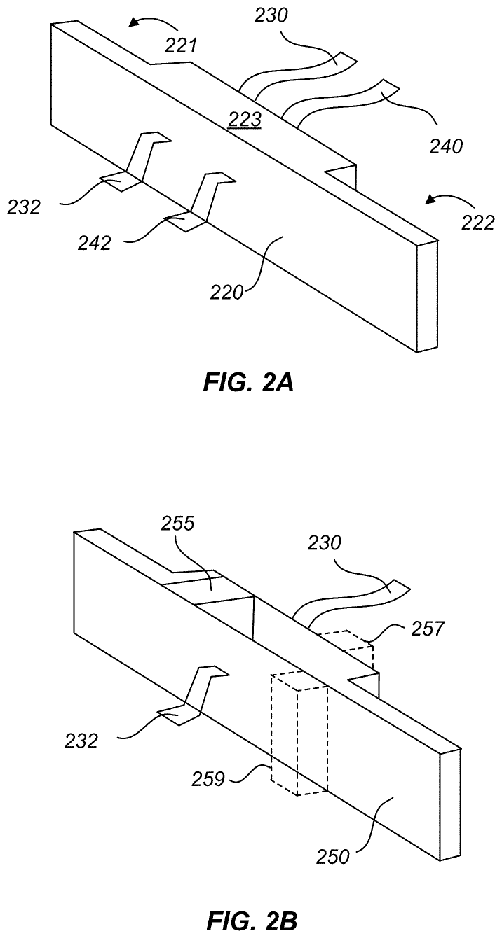

Although a pair of molded cables and electrical connectors are illustrated in FIG. 1A, embodiments of the present invention are not limited to a pair and more than two molded cables or wires, and more than two internal electrical connectors can be utilized. Thus, in addition to providing electrical contact to an anode/cathode inside the IGU, embodiments can utilize an additional ground wire, for example, to provide a ground connect to the frame of the IGU, additional connectivity to multiple power generating strings of cells in the IGU, or the like. Moreover, in addition to the electrical connection between the molded cables and the electrical connectors being present in the body of the corner key integrated electrical connection unit, other electronics, for example, a bypass diode, such as a Schottky diode or a p-n diode or an active diode, a blocking diode, DC-DC power conversion electronics, mean power point tracking (MPPT) electronics, or the like, can be positioned in the body of the corner key integrated electrical connection unit or attached to the corner key integrated electrical connection unit. As an example, if electronics are attached to the corner key integrated electrical connection unit, they can be mounted inboard toward the center of the IGU or outboard. Additional description related to these options is provided in relation to FIG. 2B.

In one embodiment, molded cables 110 and 112 and electrical connectors 114 and 116 are bonded together at bonding locations. The material that forms the body of corner key integrated electrical connection unit 120 is then extruded, poured, or otherwise placed in a manner such that the bonding locations are disposed in the body of the corner key integrated electrical connection unit. In some embodiments, additive manufacturing processes are utilized to manufacture one or more of the components illustrated herein. Thus, the bonding locations are sealed inside the body of the corner key integrated electrical connection unit. As an example, after the molded cables and the electrical connectors are electrically bonded, for example, using a solder bond, a top half and a bottom half could be joined and bonded to form the corner key integrated electrical connection unit with the electrical bond, e.g., solder bond, sealed inside the corner key integrated electrical connection unit. Alternatively, after the molded cables and the electrical connectors are electrically bonded, for example, using a solder bond, the bonded wires can be placed in a mold and the material of the corner key integrated electrical connection unit poured into the mold to seal the electrical bond inside the body of the corner key integrated electrical connection unit. Thus, some embodiments of the present invention utilize a transition from molded cables to a solid electrical connector at a position in the body of the corner key integrated electrical connection unit to provide a hermetic seal in conjunction with electrical conductivity through the corner key integrated electrical connection unit. The inventors have determined that the gas sealability of integrated units that are fabricated using a molded element is much higher than a comparable unit that would be fabricated using one or more apertures passing through the unit plugged with mechanical stops, epoxy, or the like. In particular, since conventional IGUs lack internal photovoltaic units, conventional spacer frames do not have electrical wiring passing through the spacer frame. In the embodiments described herein, IGUs are provided that are characterized by a high level of gas sealability (e.g., a hermetic seal) while enabling electrical connectivity between the solar cell disposed in the IGU and external electronics. Thus, the unique challenges inherent in electrically active IGUs are addressed by the various embodiments described herein.

Moreover, in some embodiments, a single molded cable is utilized. FIG. 1B is a simplified schematic diagram illustrating a corner key integrated electrical connection unit, including an integrated electrical connection unit having a single electrical connector according to an embodiment of the present invention. Utilizing a single electrical connector can enable contact to a first busbar at a first location, for example, one corner of the IGU, using a first corner key integrated electrical connection unit, and contact to a second busbar at a second location, for example, a second corner of the IGU, using a second corner key integrated electrical connection unit. Thus, as illustrated in FIG. 1B, molded cable 110 terminates at, or inside, corner key integrated electrical connection unit 130 and is electrically connected to electrical connector 114.

FIG. 2A is a simplified schematic diagram illustrating a side-mounted integrated electrical connection unit according to an embodiment of the present invention. The discussion provided in relation to corner key integrated electrical connection unit 120 above is applicable to side-mounted integrated electrical connection unit 220 as appropriate.

A side-mounted integrated electrical connection unit, which can also be referred to as a straight integrated electrical connection unit, may be preferable in some embodiments, as this offers more space for integration of wires and components, does not potentially generate heat (electrical failure or diodes) at the mechanically stressed corner, and does not put wire strain on the glass corner.

In one embodiment, molded cables 230 and 240 and electrical connectors 232 and 242 are bonded together at bonding locations. The material that forms the body of side-mounted integrated electrical connection unit 120 is then extruded, poured, or otherwise placed in a manner such that the bonding locations are disposed in the body of the side-mounted integrated electrical connection unit. In some embodiments, additive manufacturing processes are utilized to manufacture one or more of the components illustrated herein. Thus, the bonding locations are sealed inside the body of the side-mounted integrated electrical connection unit. As an example, after the molded cables and the electrical connectors are electrically bonded, for example, using a solder bond, a top half and a bottom half could be joined and bonded to form the side-mounted integrated electrical connection unit with the electrical bond, e.g., solder bond, sealed inside the side-mounted integrated electrical connection unit. Alternatively, after the molded cables and the electrical connectors are electrically bonded, for example, using a solder bond, the bonded wires can be placed in a mold and the material of the side-mounted integrated electrical connection unit poured into the mold to seal the electrical bond inside the body of the side-mounted integrated electrical connection unit. Thus, some embodiments of the present invention utilize a transition from molded cables to a solid electrical connector at a position in the body of the side-mounted integrated electrical connection unit to provide a hermetic seal in conjunction with electrical conductivity through the side-mounted integrated electrical connection unit.

FIG. 2B is a simplified schematic diagram illustrating a side-mounted integrated electrical connection unit having a single electrical connector according to an embodiment of the present invention. As discussed in relation to FIG. 1B, the integration of two or more electrical connectors is not required by the present invention and, depending on the implementation, a single molded cable 230 and electrical connector 232 can be utilized. As an example, implementations using single electrical connector 232 can enable contact to a first busbar at a first location, for example, along one side of the IGU, using a first side-mounted integrated electrical connection unit, and contact to a second busbar at a second location, for example, along a second side (e.g., an opposing side) of the IGU, using a second side-mounted integrated electrical connection unit. Thus, as illustrated in FIG. 1B, molded cable 230 terminates at, or inside, side-mounted integrated electrical connection unit 250 and is electrically connected to electrical connector 232.

Referring to FIG. 2B, electronics 255, for example, a bypass diode, such as a Schottky diode or a p-n diode or an active diode, a blocking diode, DC-DC power conversion electronics, mean power point tracking (MPPT) electronics, or the like, are integrated into the body of side-mounted integrated electrical connection unit 250. Thus, electrical signals generated in the IGU and carried out of the IGU using electrical connector 232 as well as electrical signals generated external to the IGU and carried into the IGU using molded cable 230 can be processed using electronics 255. In addition to electronics being integrated into the body of the side-mounted integrated electrical connection unit or corner key integrated electrical connection unit, optional electronics 257 and 259 are illustrated at locations that are external to the body of side-mounted integrated electrical connection unit 250 as well internal to the body of side-mounted integrated electrical connection unit 250, respectively. Thus, depending on the physical dimensions, cooling requirements, and the like of the electronics, which can take the form of discreet electronics, printed circuit board(s), or the like, the electronics can be integrated with the structures described herein. One of ordinary skill in the art would recognize many variations, modifications, and alternatives. Although not illustrated in relation to FIGS. 1A and 1B, electronics such as optional electronics 257 and 259 can also be integrated into the body of the corner key integrated electrical connection units illustrated in FIGS. 1A and 1B at locations that are external to the body of the corner key integrated electrical connection unit as well internal to the body of the corner key integrated electrical connection unit.

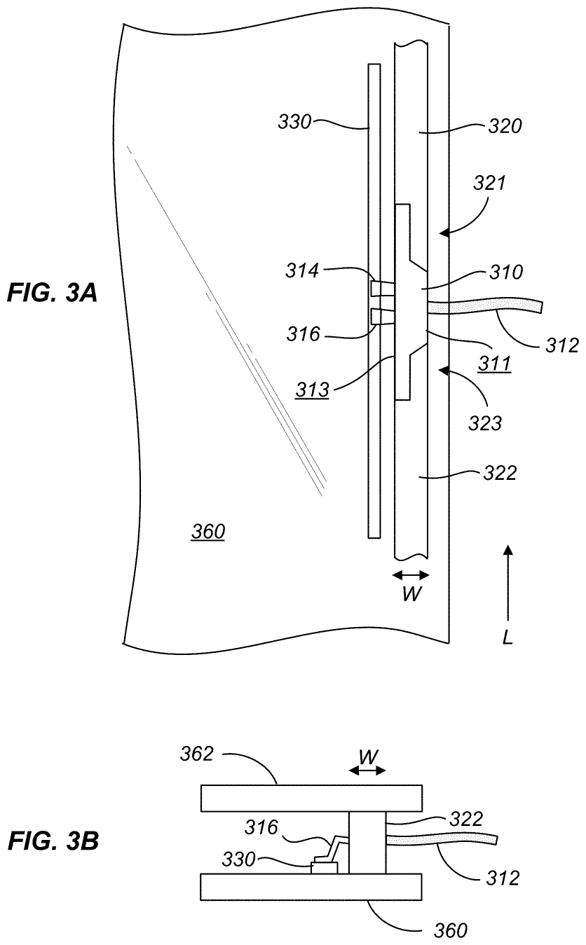

FIG. 3A is a simplified plan view schematic diagram illustrating a side-mounted integrated electrical connection unit having two electrical connectors electrically connected to a busbar of a solar panel according to an embodiment of the present invention.

Although FIGS. 3A and 3B illustrated a side-mounted integrated electrical connection unit integrated into the spacer frame, it will be appreciated that a corner key integrated electrical connection unit, as illustrated in FIG. 1A, could be integrated into the spacer frame at one or more corners of the spacer frame. One of ordinary skill in the art would recognize many variations, modifications, and alternatives.

Referring to FIG. 3A, side-mounted integrated electrical connection unit 310 is integrated with and joined to portion 320 of the spacer frame and portion 322 of the spacer frame. As illustrated in FIG. 3A, side-mounted integrated electrical connection unit 310 includes a central portion that is thicker than edge portions. Referring to FIG. 2A, side-mounted integrated electrical connection unit 220 includes central portion 223 and side portions 221 and 222. As this geometry enables portions 320 and 322 of the spacer frame, which have a matching geometry, to form interlocking connections, as illustrated in regions 321 and 323, in which the thickness of the spacer frame decreases to complement the edge portions of the side-mounted integrated electrical connection unit. Although the edge portions of the side-mounted integrated electrical connection unit and the matching portions of the spacer frame are illustrated as planar, this is not required by the present invention and other surface features can be utilized to enhance the interlocking characteristic of regions 321 and 323. Moreover, although not illustrated in FIG.

3A, one or more sealants can be utilized to join and seal the side-mounted integrated electrical connection unit and the spacer frame in regions 321 and 323. Utilizing the interlocking structures illustrated in regions 321 and 323, a constant width W can be implemented for the spacer frame and the integrated corner key integrated electrical connection units and/or side-mounted integrated electrical connection unit. In alternative embodiments, the thickness of the side-mounted integrated electrical connection unit is greater than the thickness of the spacer frame, resulting in design in which surface 311 of side connection unit 310 extends outboard (i.e., to the right in FIG. 3A) with respect to the spacer frame. Moreover, in some embodiments, the thickness of the side-mounted integrated electrical connection unit is greater than the thickness of the spacer frame such that surface 313 of side-mounted integrated electrical connection unit 310 extends inboard (i.e., to the left in FIG. 3A) with respect to the spacer frame.

FIG. 3B is a simplified cross sectional view schematic diagram illustrating a side-mounted integrated electrical connection unit having an electrical connector electrically connected to a busbar of a solar panel according to an embodiment of the present invention. In FIG. 3B, the view is obtained from the perspective along line L in which the view is positioned below the structure illustrated in FIG. 3A. In addition to molded cable 312, electrical connector 316, and busbar 330, a first glass lite 360, which can be the glass lite on the outdoor side of the IGU, and second glass lite 362, which can be the glass lite on the indoor side of the IGU, are illustrated.

In the embodiment illustrated in FIG. 3B, the widths of the side-mounted integrated electrical connection unit and the spacer frame are equal to W, although, as discussed above, this is not required by the present invention.

In some embodiments, a side-mounted integrated electrical connection unit could be used with a spacer frame formed from a single piece of material with four corners, i.e., a four corners bent frame, which can be used in fabricating a sealed IGU with limited or no inert gas leakage. Rather than using several pieces of spacer frame that are joined, for example, at the corners, a single piece of spacer frame material can be bent to form corners and a side-mounted integrated electrical connection unit as illustrated in FIGS. 2A and 2B can be used to join a gap in the spacer frame on one of the sides. In some embodiments, the side-mounted integrated electrical connection unit forms one side of the spacer frame, joined to a U-shaped spacer frame segment, whereas in other embodiments the spacer frame forms at least a portion of the fourth side of the spacer frame with the gap filled by the side-mounted integrated electrical connection unit. In some implementations, the use of a side-mounted integrated electrical connection unit in place of a corner key integrated electrical connection unit enables a more rugged and longer lasting IGU.

Referring to FIGS. 3A and 3B, a side-mounted integrated electrical connection unit is utilized as a component of the IGU to provide connectivity to busbar 330 that has been patterned onto the glass surface of first glass lite 360. In this embodiment, the side-mounted integrated electrical connection unit, which can also be referred to as an edge integrated electrical connection unit, slots into the spacer frame in accordance with requirements for non-electrical/wired side-mounted integrated electrical connection units or corner key integrated electrical connection units. The external molded cables, which can be implemented using solid or braided wires, emerge from the side-mounted integrated electrical connection unit and pass through the secondary seal. On the inside of the spacer frame, the electrical connectors, which can be referred to as tabs, make physical and/or electrical contact with the busbar.

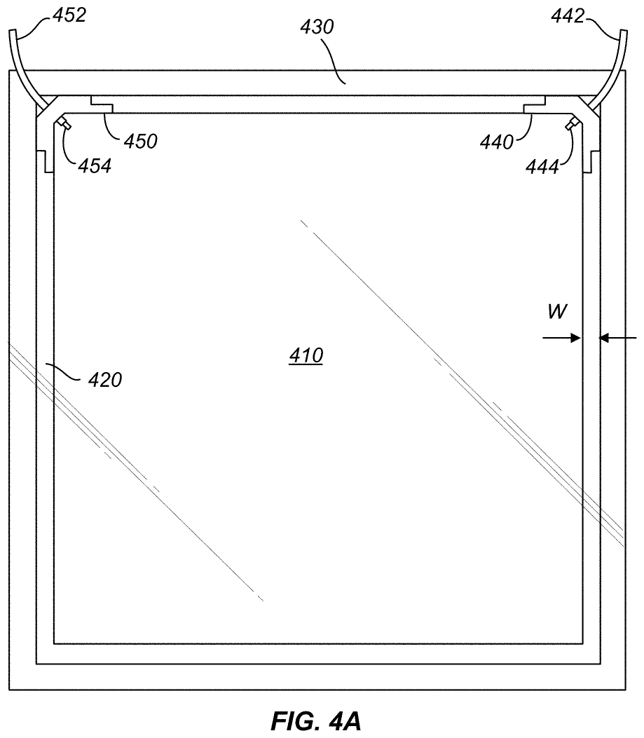

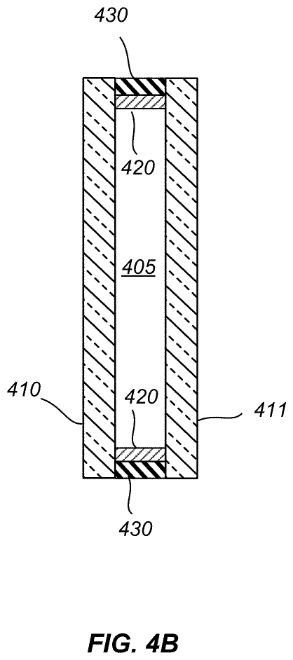

FIG. 4A is a simplified plan view schematic diagram illustrating an IGU including a set of corner key integrated electrical connection units according to an embodiment of the present invention. Referring to FIG. 4A, spacer frame 420 is illustrated behind a glass lite 410, which can be the glass lite on the indoor side of the IGU. Corner key integrated electrical connection units 440 and 450, that include a single electrical connector, are integrated into spacer frame 420.

Corner key integrated electrical connection units 440 and 450 are described more fully in relation to FIG. 1B. Sealant 430 is applied around the periphery of the IGU. Electrical connector 444 can be electrically connected to a first busbar (not shown) and electrical connector 454 can be electrically connected to a second busbar (not shown). As a result, current generated in the IGU can be carried by electrical connector 444 to molded cable 442 and by electrical connector 454 to molded cable 452. In the embodiment illustrated in FIG. 4A, the width W of the edge portions of the corner key integrated electrical connection units and the spacer frame are equal, although this is not required by the present invention.

Although two corner key integrated electrical connection units, each with a single electrical connector are illustrated in FIG. 4A, this is not required by the present invention and in other embodiments, a single corner key integrated electrical connection unit with two or more electrical connectors can be utilized. Moreover, a combination of corner key integrated electrical connection unit(s) and side-mounted integrated electrical connection units can be utilized depending on the particular application. One of ordinary skill in the art would recognize many variations, modifications, and alternatives.

FIG. 4B is a simplified cross sectional view schematic diagram illustrating the IGU including a set of corner key integrated electrical connection units shown in FIG. 4A. In the cross sectional view illustrated in FIG. 4B, first glass lite 410, for example, the glass lite on the indoor side of the IGU and second glass lite 411, for example, the glass lite on the outdoor side of the IGU enclose an air gap 405. Spacer frame 420 and sealant 430 are disposed at the periphery of the IGU. For purposes of clarity, the integrated electrical connection units, which can be corner key integrated electrical connection unit(s) or side-mounted integrated electrical connection unit(s) are not illustrated in this cross-sectional view. Typically, the one or more busbars would be mounted on the surface of second glass lite 411 facing air gap 405.

As illustrated in FIGS. 4A and 4B, the IGU has various options for the location at which power passes through the spacer frame to bring power from inside the IGU gap to outside the IGU. In some embodiments, the electrical connection is provided near a corner of the spacer frame as illustrated in FIG. 4A, for example, using a corner key integrated electrical connection unit or a side-mounted integrated electrical connection unit mounted near the corner. In other embodiments, the electrical connection is provided at a position along the side of the spacer frame.

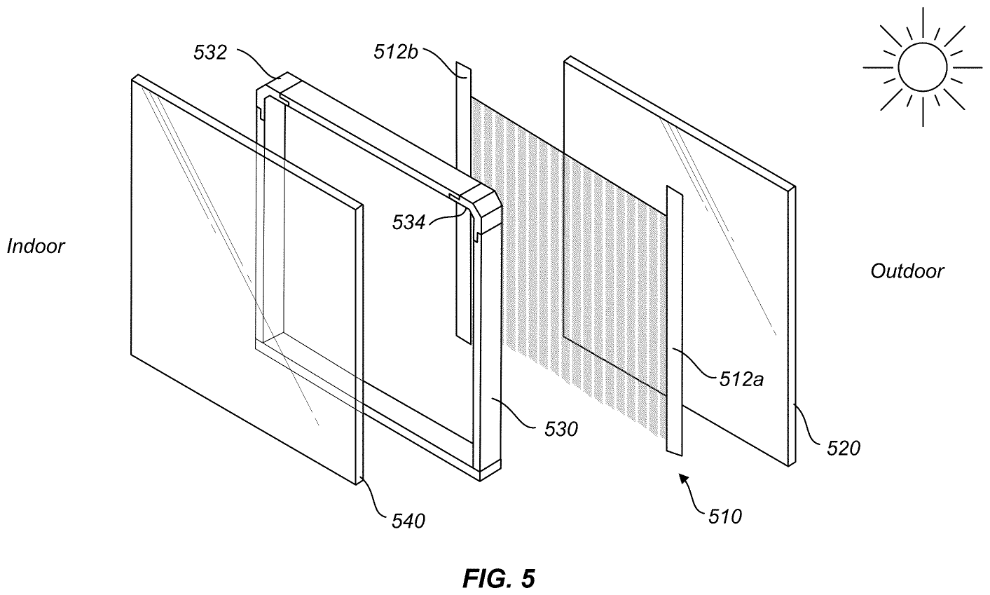

FIG. 5 is an exploded perspective view schematic diagram illustrating an IGU, including a set of corner key integrated electrical connection units according to an embodiment of the present invention. In this exemplary photovoltaic window assembly, two panes of glass with a photovoltaic module adjacent the outer pane and power output from the conduit coming from busbars on the surface of the photovoltaic module are utilized with the electrical connection being integrated with the IGU spacer frame or spacer seal. As illustrated in FIG. 5, glass lite 520, which is the glass lite on the outdoor side of the IGU, includes solar cell 510 and busbar 512a and busbar 512b, which can form positive and negative electrodes for the solar cell. In some embodiments, solar cell 510 is fabricated on glass lite 520 as a transparent photovoltaic unit. The IGU also includes spacer frame 530 that has one or more integrated electrical connection units integrated into the spacer frame. In the embodiment illustrated in FIG. 5A, first corner key integrated electrical connection unit 532 is integrated into spacer frame 530 in a first corner and second corner key integrated electrical connection unit 534 is integrated into spacer frame 530 in a second corner. For purposes of clarity, the electrical connector(s) and molded cable(s) illustrated in FIGS. 1A and 1B are not illustrated in FIG. 5, but it will be appreciated that they will be present. Additionally, for purposes of clarity, the electrical connection between the electrical connectors and the busbars illustrated in FIGS. 3A and 3B are not shown in FIG. 5, but it will be appreciated that they will be present after fabrication. For example, the electrical connector in first corner key integrated electrical connection unit 532 can be electrically connected to busbar 512b and the electrical connector in second corner key integrated electrical connection unit 534 can be electrically connected to busbar 512a.

In some embodiments, the spacer frame 530 can be an aluminum member in a rectangular shape and filled with desiccant. In some implementations, either corner key integrated electrical connection unit 120, side-mounted integrated electrical connection unit 220, or both, can be integrated into spacer frame 530 as a component of the spacer frame. Thus, depending on the geometry of the busbars, electrical connectivity can be provided at different positions on the periphery of the spacer frame.

As an example, a corner key integrated electrical connection unit having two electrical connectors could be utilized to provide electrical connectivity from the busbars to electronics external to the IGU. In another example, a first corner key integrated electrical connection unit having a single electrical connector connected to busbar 512a and a second corner key integrated electrical connection unit having a single electrical connector connected to busbar 512b could be integrated with the spacer frame to conduct current generated in the IGU to external electronics. Furthermore, a corner key integrated electrical connection unit having a single electrical connector connected to busbar 512a and a side-mounted integrated electrical connection unit having a single electrical connector connected to busbar 512b could be integrated with the spacer frame to conduct current generated in the IGU to external electronics. Additionally, a first side-mounted integrated electrical connection unit having a single electrical connector connected to busbar 512a and a second side-mounted integrated electrical connection unit having a single electrical connector connected to busbar 512b could be integrated with the spacer frame to conduct current generated in the IGU to external electronics. In another embodiment, a single side-mounted integrated electrical connection unit having two electrical connectors could be integrated with the spacer frame, with each of the two electrical connectors being connected to busbar 512a or 512b, respectively.

In embodiments that utilize a single integrated electrical connection unit, either a corner key integrated electrical connection unit or a side-mounted integrated electrical connection unit, additional busbars or other electrical leads can be fabricated as elements of solar cell 510 in order to carry electrical current from the solar cell to the electrical connectors. One of ordinary skill in the art would recognize many variations, modifications, and alternatives.

Referring to FIG. 5, solar panel 510 is positioned adjacent to first glass lite 520. In some embodiments, solar panel 510 is integrated as one or more layers deposited or otherwise formed on first glass lite 520. The solar panel includes one or more solar cell structures that generate electrical current, which is conducted to one or more busbars, 512a and 512b. Electrical connectors (not shown) are electrically bonded to the busbar(s). The electrical connectors are electrically bonded to external molded cables as discussed in relation to FIGS. 1-3B so the electrical current can pass through spacer frame 530. A second glass lite 540 is utilized to seal the IGU. Although not illustrated in FIG. 5, the electrical connectors are joined to the external molded cables at a location inside the body of the spacer frame 530.

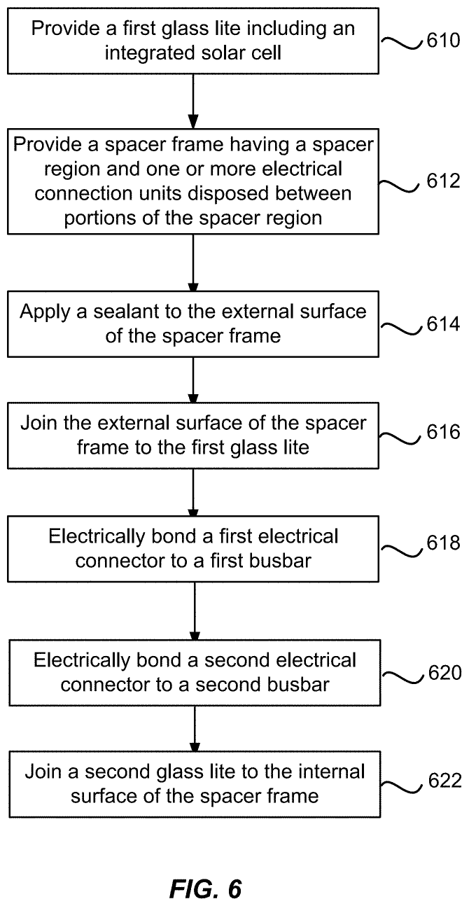

FIG. 6 is a simplified flowchart illustrating a method of assembling an insulated glass unit (IGU) with integrated electrical connection units according to an embodiment of the present invention. The method includes providing a first glass lite including an integrated solar cell comprising of a plurality of busbars (610) and providing a second glass lite. The plurality of busbars can include two busbars on opposing sides of the first glass lite as illustrated by busbar 512a and busbar 512b in FIG. 5. The method also includes providing a spacer frame having a spacer region and one or more electrical connections units disposed between portions of the spacer region. The spacer frame also has one or more electrical connectors and one or more molded cables (612). The spacer frame has an external surface and an internal surface.

The one or more electrical connection units can include a corner key integrated electrical connection unit having two electrical connectors. In another embodiment, the one or more electrical connection units can include a first corner key integrated electrical connection unit having a single electrical connector and a second corner key integrated electrical connection unit having a single electrical connector. This embodiment is illustrated by corner key integrated electrical connection unit 532 and corner key integrated electrical connection unit 534 in FIG. 5. In yet another embodiment, the one or more electrical connection units can include a corner key integrated electrical connection unit having a single electrical connector and a side-mounted integrated electrical connection unit having a single electrical connector. Moreover, the one or more electrical connection units can include a first side-mounted integrated electrical connection unit having a single electrical connector and a second side-mounted integrated electrical connection unit having a single electrical connector. As an example, a first side-mounted integrated electrical connection unit could be positioned in the vertical side of spacer frame 530 adjacent corner key integrated electrical connection unit 532 in FIG. 5 and a second side-mounted integrated electrical connection unit could be positioned in the vertical side of spacer frame 530 adjacent corner key integrated electrical connection unit 534 in FIG. 5. Furthermore, the one or more electrical connection units can include a side-mounted integrated electrical connection unit having two electrical connectors. In this embodiment, if the single side-mounted integrated electrical connection unit is positioned in the vertical side of spacer frame 530 adjacent corner key integrated electrical connection unit 534 in FIG. 5, a busbar or other electrical lead could run along the lower portion of solar cell 510 to provide electrical connectivity to busbar 512b. One of ordinary skill in the art would recognize many variations, modifications, and alternatives.

The method further includes applying a sealant to the external surface of the internal surface of spacer frame (614), joining the external surface of the spacer frame to the first glass lite (616), electrically bonding a first electrical connector of the one or more electrical connectors to a first busbar of the plurality of busbars (618), and electrically bonding a second electrical connector of the one or more electrical connectors to a second busbar of the plurality of busbars (620). Electrically bonding the electrical connectors to the busbars, which can be performed after joining the spacer frame to the first glass lite, can include welding the electrical connectors to the busbars. The method additionally includes joining the second glass lite to the internal surface of spacer frame (622).

It should be appreciated that the specific steps illustrated in FIG. 6 provide a particular method of assembling an IGU with integrated electrical connection units according to an embodiment of the present invention. Other sequences of steps may also be performed according to alternative embodiments. For example, alternative embodiments of the present invention may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. An insulated glass unit (IGU) including:
a first glass lite;
a solar cell adjacent the first glass lite, wherein the solar cell includes one or more busbars;
a spacer frame joined to the solar cell or the first glass lite and including a plurality of electrical conductors passing through the spacer frame, wherein each of the plurality of electrical conductors is electrically connected to one of the one or more busbars; and
a second glass lite joined to the spacer frame.

2. The IGU of claim 1 wherein a component of the spacer frame comprises a corner key integrated electrical connection unit through which the plurality of electrical conductors pass.

3. The IGU of claim 1 wherein a component of the spacer frame comprises a side-mounted integrated electrical connection unit through which the plurality of electrical conductors pass.

4. The IGU of claim 1 wherein the plurality of electrical conductors comprise an anode molded cable, a cathode molded cable, an anode electrical connector electrically bonded to the anode molded cable, and a cathode electrical connector electrically bonded to the cathode molded cable.

5. The IGU of claim 4 wherein the plurality of electrical conductors further comprise a ground molded cable and a ground electrical connector electrically bonded to the ground molded cable.

6. The IGU of claim 1 further comprising a bypass diode disposed in the spacer frame.

7. The IGU of claim 1 wherein the spacer frame includes an electrical connection unit comprising:
a body defined by an outer surface and an inner surface;
wherein the plurality of electrical conductors include:
a set of molded cables external to the outer surface; and
a set of electrical connectors internal to the inner surface; and
a set of electrical bonds electrically bonding one of the set of molded cables to one of the set of electrical connectors and another of the set of molded cables to another of the set of electrical connectors, wherein the set of electrical bonds are disposed in the body.

8. An electrical connection unit comprising:
a body defined by an outer surface and an inner surface;
a set of molded cables external to the outer surface;
a set of electrical connectors internal to the inner surface; and
a set of electrical bonds electrically bonding one of the set of molded cables to one of the set of electrical connectors and another of the set of molded cables to another of the set of electrical connectors, wherein the set of electrical bonds are disposed in the body.

9. The electrical connection unit of claim 8 wherein the electrical connection unit comprises a corner key integrated electrical connection unit.

10. The electrical connection unit of claim 8 wherein the electrical connection unit comprises a side-mounted integrated electrical connection unit having a central portion surrounded by two edge portions.

11. The electrical connection unit of claim 8 further comprising a spacer frame, wherein the electrical connection unit is disposed between a first portion of the spacer frame and a second portion of the spacer frame.

12. A method of fabricating an insulated glass unit (IGU), the method comprising:
providing a first glass lite including an integrated solar cell comprising a plurality of busbars;
providing a second glass lite;
providing a spacer frame having a spacer region and one or more electrical connection units disposed between portions of the spacer region and having one or more electrical connectors and one or more molded cables, wherein the spacer frame has an external surface and an internal surface;
applying a sealant to the external surface of the internal surface of the spacer frame;
joining the external surface of the spacer frame to the first glass lite;
electrically bonding a first electrical connector of the one or more electrical connectors to a first busbar of the plurality of busbars;
electrically bonding a second electrical connector of the one or more electrical connectors to a second busbar of the plurality of busbars; and
joining the second glass lite to the internal surface of the spacer frame.

13. The method of claim 12 wherein the plurality of busbars comprises two busbars on opposing sides of the first glass lite.

14. The method of claim 12 wherein the one or more electrical connection units comprises a corner key integrated electrical connection unit having two electrical connectors.

15. The method of claim 12 wherein the one or more electrical connection units comprises a first corner key integrated electrical connection unit having a single electrical connector and a second corner key integrated electrical connection unit having a single electrical connector.

16. The method of claim 12 wherein the one or more electrical connection units comprises a corner key integrated electrical connection unit having a single electrical connector and a side-mounted integrated electrical connection unit having a single electrical connector.

17. The method of claim 12 wherein the one or more electrical connection units comprises a first side-mounted integrated electrical connection unit having a single electrical connector and a second side-mounted integrated electrical connection unit having a single electrical connector.

18. The method of claim 12 wherein the one or more electrical connection units comprises a side-mounted integrated electrical connection unit having two electrical connectors.

19. The method of claim 12 wherein the first electrical connector is welded to the first busbar or the second electrical connector is welded to the second busbar.

20. The method of claim 12 wherein electrically bonding the first electrical connector and electrically bonding the second electrical connector is performed after joining the spacer frame to the first glass lite.
